(19) United States
(12) Patent Application Publication
(10) Pub. No.: US 2003/0076093 A1
(43) Pub. Date: Apr. 24, 2003

(54) Reducing orientation directivity and improving operating distance of magnetic sensor coils in a magnetic field

(75) Inventors: Ruan Lourens, Chandler, AZ (US); Dawson Steven, Scottsdale, AZ (US); Schieke Pieter, Phoenix, AZ (US)

Correspondence Address: BAKER BOTTS, LLP, 910 LOUISIANA, HOUSTON, TX, 77002-4995, US

(73) Assignee: Microchip Technology Incorporated

(21) Appl. No.: 09/983,001

(22) Filed: Oct. 18, 2001

(51) Int. Cl. G01R 33/02

(52) U.S. Cl. 324/247

(57) ABSTRACT

In a passive keyless entry (PKE) system, a PKE key-fob has magnetic sensor coils arranged in non-perpendicular and non-parallel orientations therebetween, resulting in a more uniform omnidirectional pickup pattern when sensing a time varying magnetic field source from an interrogator base station of the PKE system. The magnetic sensor coils may also be stagger tuned to reduce frequency resonance change due to mutual inductance coupling interaction and/or create a desired magnetic field frequency response pickup pattern. Reducing null zones of different orientations of the PKE key-fob results in more uniform and reliable operation of the PKE system, and tuning the magnetic sensors to operate within the correct frequency and bandwidth of the interrogation magnetic signal increases the useful operating range of the PKE key-fob.

### RELATED APPLICATIONS

This application is related to co-pending patent applications Ser. Nos. ______ [attorney docket number 068354.1169/MTI-1869/1870], entitled “Apparatus and Method of Increasing the Sensitivity of Magnetic Sensors Used in Inductively Coupled Magnetic Field Transmission and Detection Systems,” filed ______, by Ruan Lourens, Steven Dawson and Pieter Schieke, and U.S. Ser. No. ______ [attorney docket number 068354.1178/MTI-1891.US.0], entitled “Tuning of Sensor Resonant Frequency in a Magnetic Field,” filed Oct. 18, 2001, by Ruan Lourens, Paul Forton and Michel Sonnabend, both applications are hereby incorporated by reference herein for all purposes.

### FIELD OF THE INVENTION

The present invention relates generally to inductively coupled magnetic field transmission and detection systems, such as passive keyless entry (PKE) systems, and more particularly to an apparatus and method for improving orientation and operating distance of magnetic sensors employed in such systems.

### BACKGROUND OF THE INVENTION TECHNOLOGY

The use of passive keyless entry (PKE) systems in automobile, home security, and other applications has increased significantly recently. These systems have increased the convenience of entering an automobile, for example, especially when the vehicle operator's hands are full, for example, with groceries. They also are more secure than prior key-based security systems.

These wireless PKE systems typically are comprised of a base station, which is normally placed in the vehicle in automobile applications, or in the home in home applications, and one or more PKE transponders, e.g., key-fobs, communicate with the base station. In simplest terms, the base station acts as an interrogator sending a signal within a magnetic field, which can be identified by a PKE transponder. The PKE transponder acts as a responder by transmitting an electromagnetic response signal, which can be identified by the base station (e.g., uniquely coded signals). The base station generates a time varying magnetic field at a certain frequency. When the PKE transponder is within a sufficiently strong enough magnetic field generated by the base station, the PKE transponder will respond if it recognizes its code, and if the base station and PKE transponder have matching codes the door will unlock. Thus, the PKE transponder is adapted to sense in a magnetic field, a time varying amplitude magnetically coupled signal at a certain frequency. The magnetically coupled signal carries coded information (amplitude modulation of the magnetic field), which if the coded information matches what the PKE transponder is expecting, will cause the PKE transponder to communicate back to the base station via a radio frequency signal (electromagnetic wave).

The base station typically comprises a magnetic field generating coil coupled to a signal generator and an electromagnetic signal receiving antenna coupled to a receiver. A single coil, e.g., multi-turn wire inductor may be used for both the magnetic field generation from the base station interrogator and as the electromagnetic signal receiving antenna for reception of the acknowledgment signal from the PKE transponder. Typically, the frequency used for generation of the time varying magnetic field is at low frequencies, e.g., about 125 kHz (Kilohertz). When one coil is used for both magnetic field generation and electromagnetic reception, the PKE transponder also transmits at low frequency response signal, typically at the same frequency as the interrogator magnetic field generator. More advanced wireless systems may use a very high frequency (VHF) or ultra high frequency (UHF) transmission response signal, e.g., 433.92 MHz. The advantage to using a higher frequency for the response signal is greater range with lower power than what is possible with only magnetic coupling between the base station interrogator and the PKE transponder. Also small antenna size is not as distance limiting at VHF and UHF frequencies.

The PKE transponder is typically housed in a small, easily carried key-fob and the like. A very small internal battery is used to power the electronic circuits of the PKE transponder when in use. The duty cycle of the PKE transponder must, by necessity, be very low otherwise the small internal battery would be quickly drained. Therefore to conserve battery life, the PKE transponder spends most of the time in a “sleep mode,” only being awakened when a sufficiently strong magnetic field interrogation signal is detected. The PKE transponder will awaken when in a strong enough magnetic field at the expected operating frequency, and will respond only after being thus awakened and receiving a correct security code from the base station interrogator, or if a manually initiated “unlock” signal is requested by the user (e.g., unlock push button on key-fob).

Thus, it is necessary that the number of false “wake-ups” of the PKE transponder circuits be keep to a minimum. This is accomplished by using low frequency time varying magnetic fields to limit the interrogation range of the base station to the PKE transponder. The flux density of the magnetic field is known as “field intensity” and is what the magnetic sensor senses. The field intensity decreases as the cube of the distance from the source, i.e., 1/d³. Therefore, the effective interrogation range of the magnetic field drops off quickly. Thus, walking through a shopping mall parking lot will not cause a PKE transponder to be constantly awakened. The PKE transponder will thereby be awakened only when within close proximity to the correct vehicle. The proximity distance necessary to wake up the PKE transponder is called the “read range.” The VHF or UHF response transmission from the PKE transponder to the base station interrogator is effective at a much greater distance and at a lower transmission power level.

The read range is critical to acceptable operation of a PKE system and is normally the limiting factor in the distance at which the PKE transponder will awaken and decode the time varying magnetic field interrogation signal. In addition to a minimum distance required for the read range of the PKE key-fob, all possible orientations of the PKE key-fob must be functional within this read range since the keyfob may be in any three-dimensional (X, Y, Z) position in relation to the interrogator base station magnetic sending coil. To obtain three dimensional operation of the key-fob, a flat air coil is used to cover the Z-axis direction and two smaller ferrite core coils cover the Y-axis and X-axis directions. The two ferrite core coils are perpendicularly (90 degrees) oriented to each other and on the plane of the flat air coil.

Maximum read range is obtained if the magnetic field from the interrogator base station coil is undistorted close to the X-axis and Y-axis magnetic sensor coils. A problem arises, however, when the magnetic sensor coils must be shrunk in size to fit into a relatively small key-fob. This results in the PKE key-fob becoming less sensitive (read range) in certain orientations and more sensitive (read range) in others. There are two major mechanisms to which cause this non-uniform sensitivity orientation phenomena.

The first is caused when the sensor coils, battery and other circuits which comprise the PKE key-fob are in close proximity as is required for a small PKE key-fob. This close proximity of magnetic sensor coils with other components causes a distortion in the magnetic field lines around the sensor coils. Typically, if a battery is in close proximity to one end of a magnetic sensor coil it will change the magnetic field pattern around that sensor coil.

The second mechanism which causes a distorted, uneven read range is due to the close proximity of two or more of the sensor coils forming a magnetically coupled transformer having a coupling coefficient of less than one. This distortion in the read range (orientation critical sensitivity) to the magnetic field may be caused by a complex interaction of any one or a combination thereof: the individual sensor coil resonant frequencies, the complex impedance's of the sensor coil structures, the inductive coupling coefficient between coils, the angle between coils, the magnetic field direction, and/or operating frequency of the magnetic field. Any of these influences may cause a shift in the resonant frequency of one or both sensor coils away from the desired resonant frequency when sensing the interrogator magnetic field, thus resulting in a loss of sensitivity that affects the read range of the PKE system.

In actual operation in a PKE system, the pick-up coil is excited in a time varying amplitude magnetic field. When magnetic flux lines cut a coil of wire, an electric current is generated, i.e., see Maxwell's Equations for current flow in an electric conductor being cut by a magnetic field flux. Therefore the detected magnetic flux density will be proportional to the amount of current flowing in the pick-up coil. Attempts have been made to increase the read range of the PKE key-fob sensors by “tuning” the magnetic field pick-up coil to the frequency at which the base station interrogator magnetic signal generator is operating. Tuning is accomplished by electrically coupling an alternating current (AC) signal at the frequency of interest to the PKE key-fob pick-up coil and then tuning the coil for maximum signal amplitude. However, directly electrically exciting a pick-up coil does not take into account the magnetic environment and influences surrounding and proximate to the pick-up coil sensor being tuned. The magnetic pick-up sensor coil has a magnetic directional sensitivity and extraneous magnetic field modifying influences that are not accounted for when only electrically exciting this pick-up coil. There may be magnetic interaction of the sensor in test with other sensors in the PKE key-fob and would not be apparent when using directly connected electrical excitation. Accurate testing and measurement equipment is also extremely expensive when trying to directly electrically tune the pickup coil. In addition, the pick-up sensor coils are very sensitive to external circuit loading, any extraneous loading, as small as a few picofarads and/or as high as a few megohms, can influence the resonant frequency, quality factor (Q) and sensitivity of magnetic sensor coil.

Therefore, there is a need for improving the sensitivity and efficiency of electromagnetic field sensors in PKE systems by reducing the PKE key-fob structurally induced distortion of the magnetic field surrounding the sensor coils and the sensitivity degradation from interaction of the coil sensors on one another.

### SUMMARY OF THE INVENTION

The present invention overcomes the above-identified problems as well as other shortcomings and deficiencies of existing technologies by providing an apparatus, system and method for improving the read range and magnetic field sensing positional omni-directivity of a key-fob in a passive keyless entry (PKE) system. The PKE key-fob has magnetic sensor coils arranged in non-perpendicular and non-parallel orientations therebetween, resulting in a more uniform omnidirectional pickup pattern when sensing a time varying magnetic field source from an interrogator base station of the PKE system. The magnetic sensor coils may also be stagger tuned to reduce frequency resonance change due to mutual inductance coupling interaction and/or create a desired magnetic field frequency response pickup pattern. Reducing null zones of different orientations of the PKE key-fob results in more uniform and reliable operation of the PKE system, and tuning the magnetic sensors to operate within the correct frequency and bandwidth of the interrogation magnetic signal increases the useful operating range of the PKE key-fob.

In an exemplary embodiment of a PKE key-fob, according to the present invention, a plurality of magnetic field sensor coils are arranged in positional arrangements within the key-fob that are non-perpendicular and non-parallel to each other, e.g., great than zero degrees and less than 90 degrees, or greater than 90 degrees and less than 180 degrees in the X-axis, Y-axis and Z-axis directions. One or more of the plurality of magnetic field coils may be a substantially flat coil of conductive turns where the coil turns are predominantly toward the outside perimeter of the area enclosed by the coil and the conductive turns are insulated from each other. The other ones of the plurality of magnetic field sensor coils may each comprise a plurality of conductive turns, insulated from each other, and wound over a core material of high magnetic permeability, e.g., ferrite, iron, etc., that increases the inductance value of the coil so that the coil may be physically smaller in size than an air wound coil equivalent. In the alternative, all of the plurality of magnetic field sensor coils may be compact sensor coils having windings on a high permeability core. Each of the plurality of magnetic field sensor coils may be resonant at a desired frequency. Each coil may be resonant at the same frequency or each may be resonant at a different frequency, for reasons explained more fully herein.

In another exemplary embodiment of a PKE key-fob, according to the present invention, a plurality of magnetic field sensor coils are arranged in various positional arrangements within the key-fob, e.g., perpendicular, non-perpendicular, parallel, non-parallel, etc. One or more of the plurality of magnetic field coils may be a substantially flat coil of conductive turns where the coil turns are predominantly toward the outside perimeter of the area enclosed by the coil and the conductive turns are insulated from each other. The other ones of the plurality of magnetic field sensor coils may each comprise a plurality of conductive turns, insulated from each other, and wound over a core material of high magnetic permeability, e.g., ferrite, iron, etc., that increases the inductance value of the coil so that the coil may be physically smaller in size than an air wound coil equivalent. In the alternative, all of the plurality of magnetic field sensor coils may be compact sensor coils having windings on a high permeability core. Each of the plurality of magnetic field sensor coils may be resonant at a different frequency so that detection sensitivity of the magnetic field by the sensor coils is maximized for all positional orientations of the PKE key-fob. Stagger tuning of the sensor coils to slightly different frequencies but near the frequency of the interrogator thereby reduces interaction between the coils that may reduce the detection sensitivity over some of the position orientations of the PKE key-fob.

Tuning of the sensor coils, according to the invention, may be accomplished through normal means, e.g., self resonance, fixed or variable capacitors in parallel or series with the coil (parallel or series resonant circuit, respectively), adjustable core slugs in the coils, adjustable number of coil turns, in phase/out of phase tuning coil loop, etc. Resistor loading may also be introduced to adjust the Q of each of the tuned circuit sensor coils to a desired value. The sensor coils may be either parallel and/or series tuned resonant circuits. Tuning of the sensor coils is more fully described in co-pending patent application U.S. Ser. No. ______ [attorney docket number 068354.1178/MTI-1891.US.0] entitled “Tuning of Sensor Resonant Frequency in a Magnetic Field,” filed Oct. 18, 2001, by Ruan Lourens, Paul Forton and Michel Sonnabend, and is hereby incorporated by reference herein for all purposes.

A technical advantage of the present invention is improved read range at all positional orientations of the PKE key-fob. Another technical advantage is increased sensitivity of the magnetic sensors due to a reduction of detuning effects from mutual inductance coupling between coils.

### BRIEF DESCRIPTION OF THE DRAWINGS

A more complete understanding of the present disclosure and advantages thereof may be acquired by referring to the following description taken in conjunction with the accompanying drawings wherein:

FIG. 1 is a schematic isometric diagram of magnetic sensor coil orientations, according to the present invention;

FIG. 2 is a schematic plan view of magnetic sensor coil orientations, according to the present invention;

FIG. 3 is a schematic elevational view of magnetic sensor coil orientations, according to the present invention;

FIG. 4 is a schematic diagram of a parallel resonant sensor coil circuit having a variable capacitor as the tuning element;

FIG. 5 is a schematic diagram of a parallel resonant sensor coil circuit having a variable inductor as the tuning element; and

FIG. 6 is a schematic diagram of a series resonant sensor coil circuit having a variable inductor as the tuning element.

The present invention may be susceptible to various modifications and alternative forms. Specific embodiments of the present invention are shown by way of example in the drawings and are described herein in detail. It should be understood, however, that the description set forth herein of specific embodiments is not intended to limit the present invention to the particular forms disclosed. Rather, all modifications, alternatives, and equivalents falling within the spirit and scope of the invention as defined by the appended claims are intended to be covered.

### DETAILED DESCRIPTION OF THE SPECIFIC EMBODIMENTS

Referring now to the drawings, the details of an exemplary specific embodiment of the invention is schematically illustrated. FIG. 1 illustrates a schematic isometric diagram of magnetic sensor coil orientations, according to specific exemplary embodiments of the present invention. Three dimensional space is represented by X, Y and Z vectors. A PKE key-fob, generally represented by the numeral 100, has magnetic field sensor coils 102, 104 and 106. More or less sensor coils may be utilized in the present invention and are contemplated herein. The sensor coils 102, 104 and 106 may be any type of coil normally used for PKE system applications. The sensor coils 102, 104 and 106 may all have high magnetic permeability cores over which coils of wire are wound so as to create a physically small a coil, or one or more of the coils may be formed in substantially a plane of two dimensions and having a plurality of turns of wire located along the perimeter of the plane, e.g., coil 102. The positional relationship of coils 104 and 106 is such that these two coils are not parallel or perpendicular along their major axis, rather they are located so that the angle α is greater than 0 degrees and less than 90 degrees, or greater than 90 degrees and less than 180 degrees, e.g., α=135 degrees or 45 degrees.

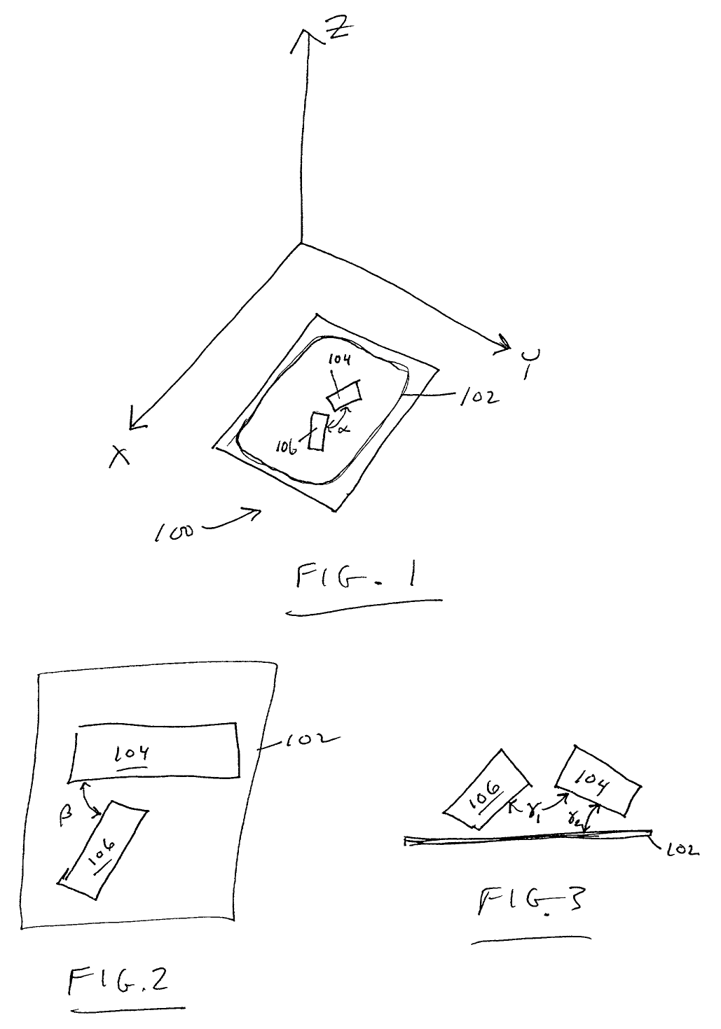

Referring to FIG. 2, depicted is a schematic plan view of magnetic sensor coil orientations, according to the present invention. The positional relationship of coils 104 and 106 is such that these two coils are not parallel or perpendicular along their major axis, rather they are located so that the angle β is greater than 0 degrees and less than 90 degrees, or greater than 90 degrees and less than 180 degrees, e.g., β=135 degrees or 45 degrees.

Referring to FIG. 3, depicted is a schematic elevational view of magnetic sensor coil orientations, according to the present invention. The positional relationship of coils 102, 104 and 106 is such that these three coils are not parallel or perpendicular along their major axis, rather they are located so that the angles γ₁ and γ₂ are greater than 0 degrees and less than 90 degrees, or greater than 90 degrees and less than 180 degrees, e.g., γ₁ and γ₂=135 degrees or 45 degrees. Therefore, none of the sensor coils 102, 104 and 106 are neither perpendicular nor parallel to one another in three dimensional space.

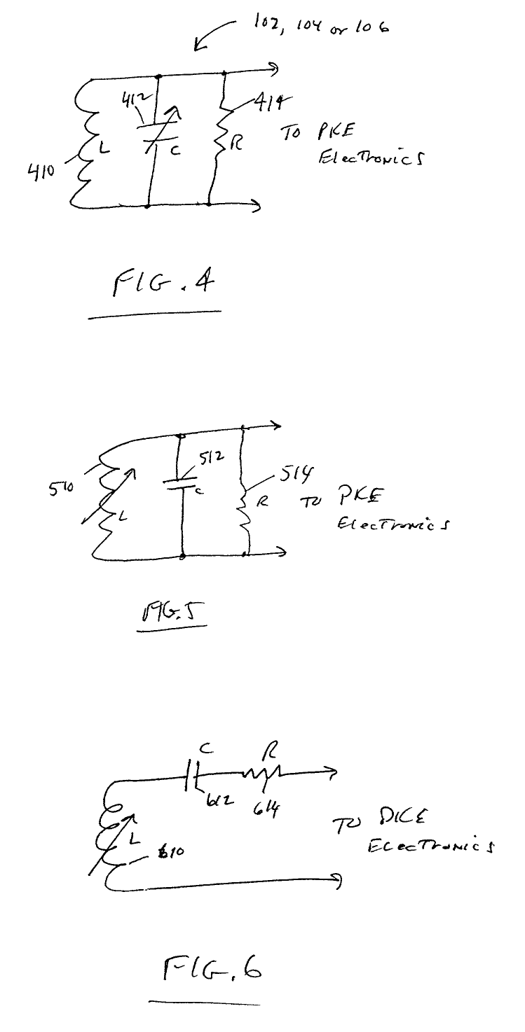

Referring to FIG. 4, depicted is a schematic diagram of a parallel resonant sensor coil circuit having a variable capacitor as the tuning element. The sensor coil in this circuit comprises an inductor 410, a variable capacitor 412 and, optionally, a resistor 414. The parallel combination of the inductor 410 and the variable capacitor 412 determine the resonant frequency of the sensor coil.

Tuning of the aforementioned circuits is more fully described in copending patent application U.S. Ser. No. ______ [attorney docket number 068354.1 178/MTI-1891.US.0], entitled “Tuning of Sensor Resonant Frequency in a Magnetic Field,” filed Oct. 18, 2001, by Ruan Lourens, Paul Forton and Michel Sonnabend, and incorporated by reference herein.

Another factor that affects the read range of a PKE key-fob is when two or more magnetic field sensor coils interact with each other and cause a shift in the resonant frequency of one or more of the coils. Read range is thereby reduced and the mutual inductive coupling between the sensor coils may also distort the pick-up pattern sensitivity of the coil(s) to the magnetic field, e.g., different read range sensitivities depending on the positional orientation of the PKE key-fob. Stagger tuning of the sensor coils may be used to eliminate or substantially reduce this undesirable interaction between the sensor coils which may result in detuning off of the desired resonant frequency and/or degradation of uniform omnidirectional reception pattern.

The present invention has been described in terms of specific exemplary embodiments. In accordance with the present invention, the parameters for a system may be varied, typically with a design engineer specifying and selecting them for the desired application. Further, it is contemplated that other embodiments, which may be devised readily by persons of ordinary skill in the art based on the teachings set forth herein, may be within the scope of the invention, which is defined by the appended claims. The present invention may be modified and practiced in different but equivalent manners that will be apparent to those skilled in the art and having the benefit of the teachings set forth herein.

What is claimed is:

1. An apparatus for passive keyless entry (PKE) comprising magnetic field sensors having improved read range at a plurality of different positional orientations within a magnetic field, comprising:
a plurality of magnetic field sensor coils, each one of said plurality of magnetic field sensor coils having a coil axis, wherein the coil axis of each one of said plurality of magnetic field sensor coils are non-perpendicular and non-parallel to the other axes.

2. The apparatus according to claim 1, wherein the coil axis of each one of said plurality of magnetic field sensor coils are at angles great than zero degrees and less than 90 degrees to the other coil axes.

3. The apparatus according to claim 1, wherein the coil axis of each one of said plurality of magnetic field sensor coils are at angles greater than 90 degrees and less than 180 degrees to the other coil axes.

4. The apparatus according to claim 1, wherein the coil axis of each one of said plurality of magnetic field sensor coils are at angles substantially 135 degrees to the other coil axes.

5. The apparatus according to claim 1, wherein each one of said plurality of magnetic field sensor coils is resonant at certain frequency.

6. The apparatus according to claim 5, wherein the certain frequency is the same for each one of said plurality of magnetic field sensor coils.

7. The apparatus according to claim 5, wherein the certain frequency is different for each one of said plurality of magnetic field sensor coils.

8. The apparatus according to claim 5, wherein the certain frequency is different for at least two of said plurality of magnetic field sensor coils.

9. The apparatus according to claim 1, wherein at one of said plurality of magnetic field sensor coils is a parallel resonant circuit.

10. The apparatus according to claim 1, wherein said plurality of magnetic field sensor coils are parallel resonant circuits.

11. The apparatus according to claim 9, wherein the parallel resonant circuit is tuned with a variable capacitor.

12. The apparatus according to claim 9, wherein the parallel resonant circuit is tuned with a variable inductor.

13. The apparatus according to claim 1, wherein at least one of said plurality of magnetic field sensor coils has resistance to lower a quality factor (Q) thereof.

14. The apparatus according to claim 1, wherein said plurality of magnetic field sensor coils are enclosed in a passive keyless entry (PKE) key-fob.

15. A method of improving read range of magnetic field sensors for a plurality of different positional orientations within a magnetic field, said method comprising the step of:
positioning a plurality of magnetic field sensor coils so that an axis of each one of said plurality of magnetic field sensor coils are non-perpendicular and non-parallel to the other axes.

16. The method according to claim 15, wherein the coil axis of each one of said plurality of magnetic field sensor coils are at angles great than zero degrees and less than 90 degrees to the other coil axes.

17. The method according to claim 15, wherein the coil axis of each one of said plurality of magnetic field sensor coils are at angles greater than 90 degrees and less than 180 degrees to the other coil axes.

18. The method according to claim 15, wherein the coil axis of each one of said plurality of magnetic field sensor coils are at angles substantially 135 degrees to the other coil axes.

19. The method according to claim 15, further comprising the steps of tuning each of said plurality of magnetic field sensor coils to a respective certain frequency.

20. The method according to claim 19, wherein the respective certain frequencies are the same.

21. The method according to claim 19, wherein the respective certain frequencies are different.

22. The method according to claim 19, wherein one of the respective certain frequencies is different than the other ones of the respective certain frequencies.

23. The method according to claim 15, wherein said plurality of magnetic field sensor coils are enclosed in a passive keyless entry (PKE) key-fob.

24. A system for passive keyless entry (PKE) comprising magnetic field sensors having improved read range at a plurality of different positional orientations within a magnetic field, said system comprising:
a passive keyless entry (PKE) transponder comprising a plurality of magnetic field sensor coils, each one of said plurality of magnetic field sensor coils having a coil axis, wherein the coil axis of each one of said plurality of magnetic field sensor coils are non-perpendicular and non-parallel to the other axes.

25. The system according to claim 24, wherein the PKE transponder is adapted to read interrogation information in a magnetic field generated by an interrogator.

26. The system according to claim 24, wherein said passive keyless entry (PKE) transponder is enclosed in a key-fob.
